(19) United States
(12) Patent Application Publication
(10) Pub. No.: US 2015/0330897 A1
(43) Pub. Date: Nov. 19, 2015

(54) IMAGE SENSOR AND METHOD FOR MEASURING REFRACTIVE INDEX

(71) Applicant: Semiconductor Components Industries, LLC, Phoenix, AZ (US)

(72) Inventor: Christopher Parks, Rochester, NY (US)

(21) Appl. No.: 14/277,144

(22) Filed: May 14, 2014

(51) Int. Cl. G01N 21/41

(52) U.S. Cl. CPC G01N 21/4133; G01N 2021/1765

(57) ABSTRACT

An image sensor and method for measuring a refractive index of a material includes a semiconductor substrate having an exposed surface for facing the material, an array of pixels on the semiconductor substrate spaced from the exposed surface, and a light source on the semiconductor substrate configured to emit light into the semiconductor substrate toward the exposed surface to reflect the light off the exposed surface toward the array of pixels, wherein the array of pixels detect the light reflected by the exposed surface for calculating the refractive index of the material.

### BACKGROUND OF THE INVENTION

1. Field of the Invention

The present invention relates generally to image sensors and, more particularly to, an image sensor and method for measuring refractive index of a material.

2. Description of the Related Art

It is known to provide a device for measuring a refractive index of a material. One such conventional device uses light transmitted through an optical fiber in contact with a liquid material for measuring a refractive index of the liquid material. Current measurement techniques for measuring chemical concentration of the liquid material using refractive index require laser light injected into the optical fiber. When this occurs, a portion of the optical fiber is in contact with the liquid material to be tested and the light injected by a laser into the optical fiber and into the liquid material. Injected light comes into contact with the surface of the liquid material and is reflected off the surface. A detector separate from the optical fiber is used to detect the reflected light for measuring the refractive index of the liquid material.

One disadvantage of conventional devices is that they require a separate light source and a separate detector. Another disadvantage of conventional devices is that they require lasers or fiber optics. Yet another disadvantage of conventional devices is that changes in the material effect the transmission of light through the optical fiber. Therefore, it is desirable to provide an image sensor that integrates the light source and detector into one component. It is also desirable to provide an image sensor that eliminates the use of lasers or fiber optics. Thus, there is a need in the art to provide an image sensor that meets at least one of these desires.

### SUMMARY OF THE INVENTION

The present invention provides an image sensor for measuring a refractive index of a material. The image sensor includes a semiconductor substrate having an exposed surface facing the material and an array of pixels on the semiconductor substrate spaced from the exposed surface. The image sensor also includes a light source on the semiconductor substrate configured to emit light into the semiconductor substrate toward the exposed surface to reflect the light off the exposed surface toward the array of pixels, wherein the array of pixels detect the light reflected by the exposed surface for calculating the refractive index of the material.

In addition, the present invention provides a method for measuring a refractive index of a material with the use of an image sensor including a semiconductor substrate having an exposed surface for facing the material, an array of pixels on the semiconductor substrate, and a light source on the semiconductor substrate. The method includes the steps of emitting light into the semiconductor substrate from the light source toward the exposed surface, reflecting the light off the exposed surface and toward the array of pixels, and detecting the light reflected from the exposed surface with the array of pixels. The method also includes the steps of calculating the refractive index of the material based on the detected light.

One advantage of the present invention is that a new image sensor and method is provided for measuring a refractive index of a material. Another advantage of the present invention is that the image sensor includes an integrated light source and detector. Yet another advantage of the present invention is that the image sensor has a relatively compact integrated light source and detector and does not require separate components. Still another advantage of the present invention is that the image sensor and method does not require lasers, optical fibers, or light modification. A further advantage of the present invention is that the image sensor and method uses a single silicon sensor as both the light source and the detector for the purpose of measuring refractive index of a material. Yet a further advantage of the present invention is that the image sensor has the light source present thereon, making for a very compact sensing unit. Still a further advantage of the present invention is that the image sensor and method can be used to measure a chemical composition of liquid materials.

Other features and advantages of the present invention will be readily appreciated, as the same becomes better understood, after reading the subsequent description taken in conjunction with the accompanying drawings.

### BRIEF DESCRIPTION OF THE DRAWINGS

FIG. 1 is a diagrammatic view of one embodiment of an image sensor, according to the present invention, illustrating emitted and reflected light.

FIG. 2 is a view similar to FIG. 1 illustrating a distance, d, from a transistor drain to a location where a first totally reflected photon is detected at a pixel.

FIG. 3 is a diagrammatic view of the image sensor of FIGS. 1 and 2 illustrating an ideal location of a transistor along an entire side of an array of pixels.

FIG. 4 is a graphical view illustrating a measured index of refraction vs. distance for a silicon substrate thickness of 675 μm for the image sensor of FIGS. 1 and 2.

FIG. 5 is a diagrammatic view of another embodiment, according to the present invention, of the image sensor of FIGS. 1 and 2.

FIG. 6 is a diagrammatic view of the image sensor of FIG. 5 illustrating emitted and reflected light.

### DESCRIPTION OF THE PREFERRED EMBODIMENT(S)

With reference to the Figures, wherein like numerals indicate like parts throughout the several views, one embodiment of an image sensor 10, according to the present invention, is shown for measuring refraction of a material 12. The material 12 is, for example, of a liquid type. In one embodiment, the image sensor 10 is used to measure a chemical concentration of the liquid material 12 such as chlorinated water. By measuring the change of refractive index of the liquid material 12, the chemical concentration of the liquid material 12 can be measured. It should be appreciated that the image sensor 10 may be used to measure the refractive index of other types of materials.

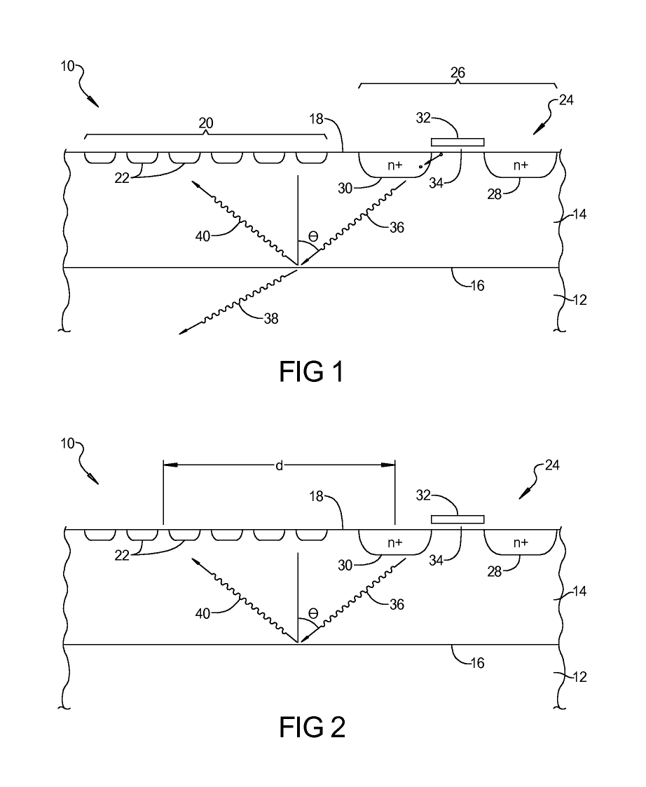

Referring to FIG. 1, the image sensor 10 includes a semiconductor substrate 14. The semiconductor substrate 14 is made of a semiconductor material such as silicon, but may be made of any suitable semiconductor material. The semiconductor substrate 14 is generally rectangular in shape, but may be any suitable shape. The semiconductor substrate 14 includes an exposed surface 16 on one side for facing the material 12 and a substrate surface 18 on another side spaced from the exposed surface 16. The exposed surface 16 may be planar or non-planar. It should be appreciated that, in one application, the material 12 being measured is a liquid in contact with the semiconductor substrate 14.

The image sensor 10 also includes an array 20 of pixels 22 on the semiconductor substrate 14. The pixels 22 are of a photo-sensitive type. The array 20 of pixels 22 is disposed in or on the substrate surface 18. It should be appreciated that the array 20 of pixels 22 is generally rectangular in shape, but may be any suitable shape. It should also be appreciated that the pixels 22 detect light and produce a charge packet corresponding to the light detected as is known in the art.

The image sensor 10 also includes a light source, generally indicated at 24, on the semiconductor substrate 14. The light source 24 is disposed on the substrate surface 18 adjacent the array 20 of pixels 22. In one embodiment, the light source 24 is a transistor 26 such as a MOSFET transistor. The transistor 26 includes a source 28 and a drain 30. The source 28 and drain 30 are of an n+ dopant on or in the semiconductor substrate 14. The transistor 26 also includes a gate 32 disposed between the source 28 and drain 30 and separated from the substrate surface 18 by an insulating layer 34. It should be appreciated that a voltage from the image sensor 10 on the gate 32 controls the amount of current flow from the source 28 to the drain 30. It should also be appreciated that the drain voltage is high enough such that electrons flowing under the gate 32 experience a large potential drop from under the gate 32 to the drain 30. It should further be appreciated that the large potential drop creates hot electrons that can emit a photon, generally indicated at 36, as is well known in the art.

The majority of the photons 36 have a wavelength near the energy gap of the semiconductor substrate 14, for example, silicon at 1.12 μm (at room temperature). These photons 36 are not easily absorbed by the semiconductor substrate 14. For example, the absorption length in silicon is approximately 5 mm at room temperature. The long absorption length means the photons 36 can reflect off the exposed surface 16 of the semiconductor substrate 14 and be detected by the array 20 of pixels 22.

As illustrated in FIG. 1, if the angle θ that a photon 36 reflects off the exposed surface 16 of the semiconductor substrate 14 is greater than a critical angle θ_{C} given by:

$${θ}_{C} = {sin}^{- 1} ( \frac{n}{{n}_{Si}} ) \qquad ( 1 )$$

then the photon 36 will totally be reflected by the exposed surface 16 thereby creating a reflected photon 40. The intensity of a transmitted photon 38 will be zero. The reflected photon 40 will be detected by the array 20 of pixels 22.

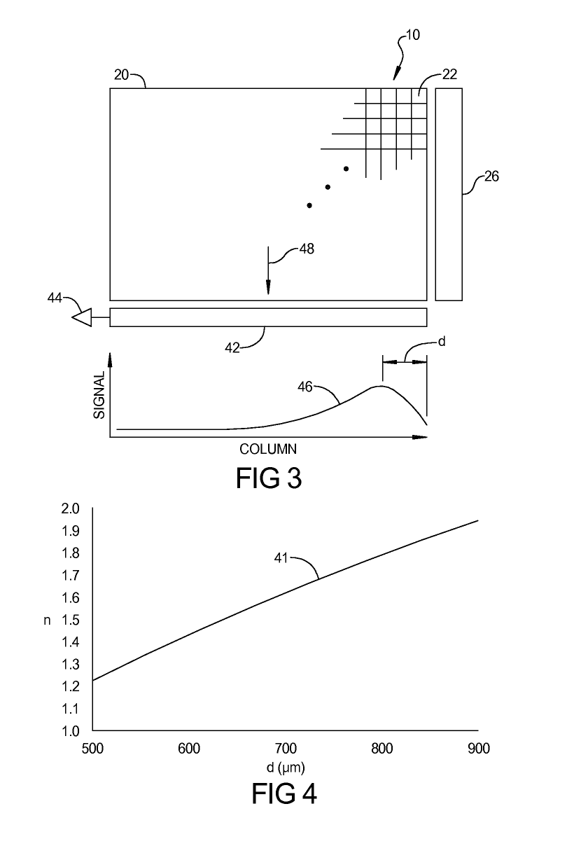

Referring to FIG. 2, a distance, d, exists from the drain 30 of the transistor 26 to a location where the first totally reflected photon 40 is detected at one of the pixels 22. If t is the thickness of the semiconductor substrate 14, there will be total internally reflected photons 40 detected. It should be appreciated that there will be many reflected photons 40 at a distance greater than d, and fewer reflected photons at a distance less than d. It should also be appreciated that the typical intensity profile across the pixel array 20 is shown in FIG. 3 to be described.

The critical angle θ_{C} of the photon 36 will be equal to:

$${θ}_{C} = {tan}^{- 1} ( \frac{d}{2 c} ) \qquad ( 2 )$$

Combining equations (1) and (2) gives a refractive index η of the material 12 in contact with the exposed surface 16 of the semiconductor substrate 14 in the following equation:

$$n = \frac{{dn}_{Si}}{\sqrt{4 {t}^{2} + {d}^{2}}}$$

FIG. 4 illustrates a curve 41 of what a measured index of refraction η would be vs. distance d for a silicon semiconductor substrate 14 having a thickness t of 675 μm.

Referring to FIG. 3, for the image sensor 10, the ideal location of the transistor 26 is along the entire side of the array 20 of pixels 22. If the array 20 of pixels 22 is a charge coupled device (CCD), the image sensor 10 includes a horizontal CCD (HCCD) shift register 42 along a bottom or horizontal edge of the array 20 of pixels 22. In one embodiment, the HCCD shift register 42 is of a low voltage type. The image sensor 10 includes an output amplifier 44 located on the opposite side from the transistor 26 so that transistors (not shown) in the output amplifier 44 do not corrupt the signal. After the horizontal signal profile of FIG. 3 is digitized, a curve 46 can be fitted to the signal profile to more accurately extract the refractive index of the material 12 in contact with the silicon substrate 14. It should be appreciated that the curve 46 in FIG. 3 is a graph of signal versus column of pixels 22 for the intensity of light on the exposed side 16 of the semiconductor substrate 14.

Referring to FIG. 3, the pixel array 20 includes vertical charge-coupled device (CCD) (VCCD) shift registers (not shown) that shift charge packets from a row of pixels 22 one row at a time into the HCCD shift register 42 as indicated by the arrow 48. The HCCD shift register 42 serially shifts the charge packets into a high voltage charge multiplying HCCD shift register (not shown). By locating the transistor 26 of the light source 24 parallel to the VCCD shift register, every row in the VCCD shift register may be summed into the HCCD shift register 42 to dramatically increase sensitivity. It should be appreciated that the ideal CDD type would be a full frame CCD with a thick silicon epitaxial layer to increase sensitivity depth that photons can be absorbed. It should also be appreciated that the charge packet output at the end of the HCCD shift register 42 is sensed and converted into a voltage signal by the output amplifier 44. It should also be appreciated that an output circuit (not shown) is connected to an output of the output amplifier 44 and the output circuit converts the analog pixel signal into a digital pixel signal.

In the embodiment illustrated in FIGS. 1 through 3, the pixels 22 may be rectangular shaped with the short dimension being parallel to the HCCD shift register 42 to maximize the accuracy of the distance d. The long dimension of the pixels 22 would be parallel to the VCCD shift register to allow longer gate lengths for easier pixel manufacturing. It should be appreciated that the signal will be small so overflow drains (not shown) within the VCCD shift register would not be needed. It should also be appreciated that a lateral overflow drain (not shown) in the HCCD shift register 42 may be needed to prevent HCCD blooming caused by summing of all rows in the array 20 of the pixels 22.

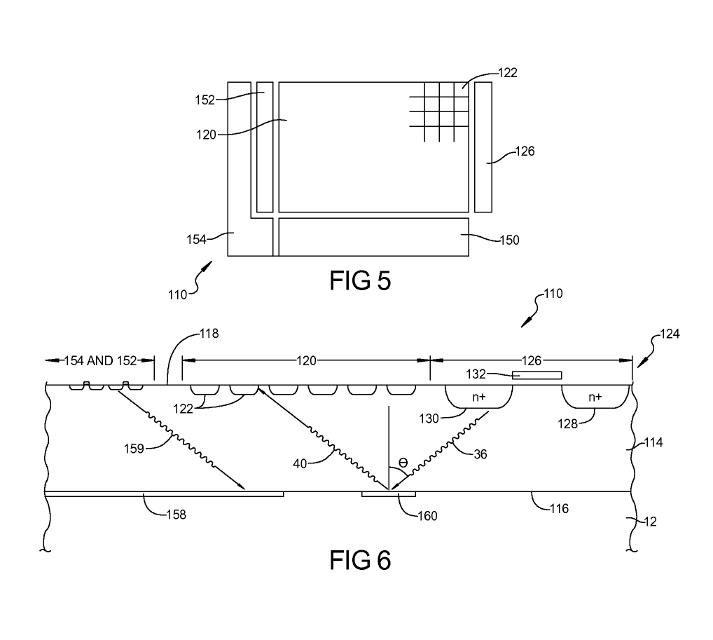

Referring to FIGS. 5 and 6, another embodiment, according to the present invention, of the image sensor 10 is shown. Like parts of the image sensor 10 have like reference numerals increased by one hundred (100). In this embodiment, the image sensor 110 includes an array 120 of pixels 122. Further, the array 120 of pixels 122 may also be of a complementary metal oxide semiconductor (CMOS) image sensor type. The array 120 consists of photodiodes and their associated readout transistors (not shown). The image sensor 110 also includes the light source 124 being the transistor 126 such as a MOSFET transistor having the source 128, drain 130, and gate 132.

As illustrated in FIG. 5, the image sensor 110 may include peripheral circuitry disposed on the semiconductor substrate 114. In one embodiment, the peripheral circuitry includes a column read out circuitry 150 positioned along a horizontal edge of the array 120, a row select circuitry 152 positioned along a vertical edge of the array 120 opposite the transistor 126, and a processor such as a digital signal processing and timing generator 154 positioned along a vertical edge of the row select circuitry 152 with one end positioned along a horizontal edge of the column read out circuitry 150. The transistor 126 is positioned along either the vertical or horizontal edges of the array 120. It should be appreciated that the pixels 122 in the array 120 do not need to be square in shape to facilitate easier placement in pixel circuitry. It should also be appreciated that, to prevent hot electron luminescence in peripheral circuitry on the image sensor 110 from corrupting the image in the array 120, the peripheral circuitry would have to be powered down while acquiring an image in the array 120.

For operation of the image sensor 110, the data acquisition process would begin by clearing all signals from all pixels 122. Then, the power to the transistor 126 would be turned ON and the power to all peripheral circuits in the column read out circuitry 150, row select circuitry 152, and signal processing and timing generator 154 would be turned OFF. After the image of light reflected off the exposed surface 116 of the semiconductor substrate 114 has been collected, the transistor 126 is turned OFF and the power is applied to the peripheral circuits in the column read out circuitry 150, row select circuitry 152, and signal processing and timing generator 154 to enable image readout.

Referring to FIG. 6, to further prevent corruption of the image in the pixels 122 by the peripheral circuitry luminescence, the exposed surface 116 of the semiconductor substrate 114 under the peripheral circuitry and a portion of the array 120 of pixels 122 may be coated by an anti-reflection or absorbing layer 158. The layer 158 prevents light 159 from the peripheral circuitry such as the column read out circuitry 150, row select circuitry 152, and signal processing and timing generator 154 from being reflected from the exposed surface 116 of the semiconductor substrate 114 and into the array 120 of pixels 122. It should be appreciated that the signal processing and timing generator 154 can also analyze the image and directly output the index of refraction of the material 12 in contact with the exposed surface 116 of the substrate 114. It should also be appreciated that the signal processing and timing generator 154 of the peripheral circuitry may be used for the image sensor 10.

In addition, the image sensor 110 may include a transition layer 160 added between the semiconductor substrate 114 and the material 12 being measured to increase the accuracy. For example, the transition layer 160 may be a layer of silicon nitride SiN, silicon dioxide SiO₂, or a graded index of refraction from approximately n=3.5 for silicon to an index of refraction slightly larger than the material 12 being measured to increase the accuracy. It should be appreciated that having the graded index of refraction increases the critical angle θ_{C} for total internal reflection which, in turn, increases the distance, d, traveled by the light in the semiconductor substrate 114. It should also be appreciated that the transition layer 160 would also serve the purpose of protecting the exposed surface 116 of the semiconductor substrate 114 from oxidation or chemical attack. It should further be appreciated that the transition layer 160 may be used for the image sensor 10.

The CCD image sensor 10 has the advantages of noiselessly sum pixel rows together to maximize signal strength and a CCD does not have any transistors that can corrupt the signal near the transistor 26. The CMOS image sensor 110 has the advantage of providing the light illumination source and detector and processing circuitry all on one silicon substrate. Furthermore, the CMOS image sensor 110 can be powered by a single low voltage supply and be placed in a package having less than eight (8) pins.

Moreover, a method for measuring a refractive index of the material 12 with the use of the image sensor 10, 110 is disclosed. The method includes the steps of emitting light into the semiconductor substrate 14, 114 from the light source toward the exposed surface 16, 116. The method also includes the steps of reflecting the light off the exposed surface 16, 116 and toward the array 20, 120 of pixels 22, 122, detecting the light reflected from the exposed surface 16, 116 with the array 20, 120 of pixels 22, 122, and calculating the refractive index of the material 12 based on the detected light.

The method also includes the steps of measuring the distance, d, between the light source and a column of the array 20, 120 of pixels 22, 122 that detect the greatest intensity of reflected light and calculating the refractive index of the material 12 based on the measured distance. The method includes the steps of generating charge packets associated with each pixel 22, 122 of the array 20, 120 of pixels 22, 122 based on the intensity of light detected by the array 20, 120 of pixels 22, 122 and transferring the charge packets to a horizontal charge coupled device (HCCD) shift register 42 of the image sensor 10, 110. The method includes the steps of summing the charge packets from columns of the pixels 22, 122 in the horizontal charge coupled device.

Accordingly, the image sensor 10, 110 of the present invention does not require a laser, optical fibers, or light modulation. The image sensor 10, 110 of the present invention has the light source 24 present on the semiconductor substrate 14, 114, making for a very compact sensing unit.

The present invention has been described in an illustrative manner. It is to be understood that the terminology, which has been used, is intended to be in the nature of words of description rather than of limitation.

Many modifications and variations of the present invention are possible in light of the above teachings. Therefore, within the scope of the appended claims, the present invention may be practiced other than as specifically described.

What is claimed is:

1. An image sensor for measuring a refractive index of a material, said image sensor comprising:
a semiconductor substrate having an exposed surface for facing the material;
an array of pixels on said semiconductor substrate spaced from said exposed surface; and
a light source on said semiconductor substrate configured to emit light into said semiconductor substrate toward said exposed surface to reflect the light off said exposed surface toward said array of pixels, wherein said array of pixels detect the light reflected by said exposed surface for calculating the refractive index of the material.

2. An image sensor as set forth in claim 1 wherein said array of pixels is disposed on one side of said semiconductor substrate and said exposed surface is disposed on another side of said semiconductor substrate opposite the one side.

3. An image sensor as set forth in claim 2 wherein said light source is disposed on the one side of the semiconductor substrate.

4. An image sensor as set forth in claim 1 including a processor operable to calculate the refractive index of the material based on the detection of the reflected light by said array of pixels.

5. An image sensor as set forth in claim 1 wherein said light source is a transistor.

6. An image sensor as set forth in claim 5 wherein said transistor extends along an edge of said array of pixels.

7. An image sensor as set forth in claim 1 including a transition layer on said exposed surface of said semiconductor substrate.

8. An image sensor as set forth in claim 7 wherein said transition layer has a graded index of refraction.

9. An image sensor as set forth in claim 7 wherein said transition layer is silicon nitride.

10. An image sensor as set forth in claim 7 wherein said transition layer is silicon dioxide.

11. An image sensor as set forth in claim 1 wherein said semiconductor substrate is silicon.

12. An image sensor as set forth in claim 1 including peripheral circuitry disposed on said semiconductor substrate.

13. An image sensor as set forth in claim 12 including a light absorbing layer on said exposed surface of said semiconductor substrate that prevents light from said peripheral circuitry form being reflected from said exposed surface.

14. An image sensor as set forth in claim 1 wherein said image sensor is a charge coupled device.

15. An image sensor as set forth in claim 1 wherein said image sensor is a complementary metal oxide semiconductor.

16. A method for measuring a refractive index of a material with the use of an image sensor including a semiconductor substrate having an exposed surface for facing the material, an array of pixels on the semiconductor substrate, and a light source on the semiconductor substrate, said method comprising the steps of:
emitting light into the semiconductor substrate from the light source toward the exposed surface;
reflecting the light off the exposed surface and toward the array of pixels;
detecting the light reflected from the exposed surface with the array of pixels; and
calculating the refractive index of the material based on the detected light.

17. A method as set forth in claim 16 including the steps of measuring a distance between the light source and a column of the array of pixels that detect greatest intensity of reflected light and calculating the refractive index of the material based on the measured distance.

18. A method as set forth in claim 16 including the steps of generating charge packets associated with each pixel of the array of pixels based on the intensity of light detected by the array of pixels and transferring the charge packets to a horizontal charge coupled device (HCCD) of the image sensor.

19. A method as set forth in claim 18 including the steps of summing the charge packets from columns of the pixels in the horizontal charge coupled device.

20. A method as set forth in claim 16 including the steps of providing the light source as a transistor and generating the light with the transistor.

21. A method as set forth in claim 16 including the steps of contacting the exposed surface of the image sensor with the material.
